(19) United States
(12) Patent Application Publication
(10) Pub. No.: US 2024/0312924 A1
(43) Pub. Date: Sep. 19, 2024

(54) FIDUCIAL DESIGN OPTIMIZATION FOR LAND SIDE DEVICE ANYWHERE PACKAGE ASSEMBLY

(71) Applicant: Intel Corporation, Santa Clara, CA (US)

(72) Inventors: Shishir Deshpande, Chandler, AZ (US); Jung Kyu Han, Chandler, AZ (US); Gang Duan, Chandler, AZ (US); Srinivas Pietambaram, Chandler, AZ (US)

(73) Assignee: Intel Corporation, Santa Clara, CA (US)

(21) Appl. No.: 18/122,250

(22) Filed: Mar. 16, 2023

(51) Int. Cl. H01L 23/544

(52) U.S. Cl. CPC H01L 23/544; H01L 24/16; H01L 24/32; H01L 24/73; H01L 2223/54426; H01L 2224/16227; H01L 2224/32225; H01L 2224/73204

(57) ABSTRACT

Microelectronic devices, systems, and techniques are disclosed having package substrate land side fiducial structures that are readily distinguishable from adjacent interconnect structures during registration of the land side of the package substrate. The fiducial structure includes a ring shape, a double ring shape, a donut shape, a triangular shape, an H-shape, or an I-shape in contrast to the circular, square, or rectangular shape of the adjacent interconnect structure. The fiducial structure shape may also have a different size relative to the interconnect structure shape.

### BACKGROUND

The electronics industry is continually striving to produce ever faster, smaller, and more efficient computing products, including, but not limited to, personal computers, servers, and portable products such as portable computers, laptops, tablets, and the like. To meet demand for miniaturization of form factor, improve power delivery performance, and design flexibility of products, placing land side capacitors anywhere (LSC anywhere) or, more generally, placing land side discrete devices anywhere is proposed. In land side device anywhere architectures, instead of dedicated cavities on the land side of a package substrate to attach components within, the components are instead placed anywhere inside the ball grid array (BGA) or land grid array (LGA) field of the land side of the package substrate by depopulating selected pads.

Compared to current land side cavities and corresponding keep out zone (KOZ) design layout, land side device anywhere architectures have the ability to reduce spacing between interconnects of the BGA/LGA fields to capacitors or other devices as well as the spacing between interconnects of BGA/LGA fields to fiducials. This improves design efficiency and area usage but requires better placement accuracy and fiducial recognition while placing the components on the land side of the package substrate as well as inspecting the land side. Current land side device patterns and corresponding keep out zones have fiducials for placement and inspection that land side device anywhere architectures cannot have due space constraints, and other concerns.

It is with respect to these and other considerations that the present improvements have been needed. Such improvements may become critical as the desire to improve computing device characteristics becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of a microelectronic device having a package substrate with an optimized land side fiducial structure;

FIG. 1B illustrates a cross-sectional plan view of a land side of the package substrate of FIG. 1A;

FIG. 2 illustrates a cross-sectional plan view of a land side having an exemplary ring shaped fiducial structure adjacent to a circular shaped interconnect structure;

FIG. 3 illustrates a cross-sectional plan view of a land side having an exemplary thick ring shaped fiducial structure adjacent to a circular shaped interconnect structure;

FIG. 4 illustrates a cross-sectional plan view of a land side having an exemplary donut shaped fiducial structure adjacent to a circular shaped interconnect structure;

FIG. 5 illustrates a cross-sectional plan view of a land side having an exemplary double ring shaped fiducial structure adjacent to a circular shaped interconnect structure;

FIG. 6 illustrates a cross-sectional plan view of a land side having an exemplary double ring shaped fiducial structure with a thicker rings adjacent to a circular shaped interconnect structure;

FIG. 7 illustrates a cross-sectional plan view of a land side having an exemplary triangular shaped fiducial structure adjacent to a circular shaped interconnect structure;

FIG. 8 illustrates a cross-sectional plan view of a land side having an exemplary H-shaped fiducial structure adjacent to a circular shaped interconnect structure;

FIG. 9 illustrates a cross-sectional plan view of a land side having an exemplary I-shaped fiducial structure adjacent to a circular shaped interconnect structure;

FIG. 10 is a flow diagram illustrating example methods for forming a microelectronic device including an optimized land side fiducial structure;

FIGS. 11A, 11B, 11C, and 11D illustrate cross-sectional side views of device structures as the operations of methods are performed;

FIG. 12 illustrates an example microelectronic device assembly including an optimized land side fiducial structure;

FIG. 13 illustrates exemplary systems employing an optimized land side fiducial structure; and

FIG. 14 is a functional block diagram of an electronic computing device, all in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the features, structures, functions, or characteristics may be combined in any suitable manner in one or more embodiments. For example, a first embodiment may be combined with a second embodiment anywhere the features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure.

As used herein, the terms “monolithic”, “monolithically integrated”, and similar terms indicate the components of the monolithic overall structure form an indivisible whole not reasonably capable of being separated. The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials. Here, the term “coreless” generally refers to a substrate of an integrated circuit package having no core. The lack of a core allows for higher-density package architectures. as the through-vias have relatively large dimensions and pitch compared to high-density interconnects.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate. Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric. Here, the term “bond pad” generally refers to metallization structures that terminate integrated traces and vias in integrated circuit packages and dies. The term “solder pad” may be occasionally substituted for “bond pad” and carries the same meaning. Here, the term “solder bump” generally refers to a solder layer formed on a bond pad. The solder layer typically has a round shape, hence the term “solder bump”. Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

As discussed, miniaturization of form factor, improved power delivery performance, and product design flexibility are ongoing concerns of the electronics industry. Notably, placing land side devices such as capacitors anywhere on the land side of the package substrate offers advantages of reduced form factor, improved power delivery, design flexibility, and others. In land side device anywhere architectures, the components are placed anywhere inside the ball grid array (BGA), land grid array (LGA), or, generally speaking, interconnect structure array field of the land side of the package substrate by depopulating interconnect structures such as balls, pads, or the like from the array. However, accurate placement of such devices and other processing such as inspection processing becomes difficult in such land side device anywhere architectures particularly as package substrates become smaller and demands for improved registration are needed. For example, land side device anywhere architectures reduce the spacing between interconnect structures and the land side devices and the spacing between interconnect structures and fiducials used for registration. Therefore, there is a need for improved placement accuracy and fiducial recognition as the chance of misplacement increases.

For example, fiducials or fiducial structures are used to place devices such as capacitors on the land side of the package substrate, and for other processing that requires registration such as inspection, test, and others. As used herein, the term fiducial structure, fiducial marker, or fiducial indicates an object or structure placed on a package substrate that is to be within a field of view of an imaging system of a tool that is to process the package substrate, such that the fiducial is used as a point of reference for the tool. The tool that used the fiducial structure may be a pick and place tool, an inspection tool, or the like. In some embodiments, the tool processes a single package substrate unit and the fiducial structures are at two corners (e.g., diagonal corners of the single package substrate unit). In some embodiments, the tool processes a package substrate panel containing a number of package substrate units and the fiducial structures are at two corners (e.g., diagonal corners of the single package substrate unit) of each of the package substrate units or some of the package substrate units. For example, a package substrate panel may include four to 70 (or more) package substrate units that will be segmented after processing.

The package substrate units, after attachment of devices on the land side and/or after other processing, are then further processed by, for example, attaching one or more integrated circuit (IC) devices or dies to a die side of the package substrate. The die side is opposite the land side. After land side device attachment and die attachment, the package may be incorporated in any suitable electronics device by attaching the land side to a host board such as a motherboard. In some embodiments, the resultant device or apparatus includes a package substrate having a die side and land side such that the land side includes a dielectric material and/or passivation material such as a solder resist. The land side includes an array of interconnect structures such that some of the interconnect structures of the array are not present and are replaced by devices such as capacitors. The interconnect structures may be balls (e.g., solder balls) or lands (e.g., metal pads or lands) to connect the package substrate to a host board. Such interconnect structures may be characterized as second level interconnects (with first level interconnects coupling die side IC dies to the package substrate).

A fiducial structure is on the land side and adjacent to one or more of the interconnect structures. The fiducial structure is used for process registration, as discussed. The fiducial structure is the same material as the interconnect structures or another material different than the discussed dielectric material. In either case, the fiducial structure, when imaging, contrasts with the surrounding material (e.g., dielectric material) of the land side of the package substrate. In some embodiments, the fiducial structure is adjacent to a corner of the package substrate. The interconnect structure has a first lateral cross-sectional shape along or over the land side and the fiducial structure has a second lateral cross-sectional shape along or over the land side. As used herein the term lateral cross-sectional shape indicates a shape taken at plane substantially parallel to the land side. Notably, the first shape and the second shape are different to advantageously allow the fiducial to be distinguished from the interconnect structure during registration. In some embodiments, the second shape (i.e., the shape of the fiducial) includes or is a triangle, which is distinguishable from the typically circular or rectangular interconnect structure shape. In some embodiments, the second shape (i.e., the shape of the fiducial) includes a segment of metal separating regions of the dielectric material. For example, the segment may be an annulus or similar shape which is again distinguishable from the typically solid circular or rectangular interconnect structure shape. Other shapes and implementations are discussed herein below. The discussed techniques enable land side device anywhere architectures through fiducial design optimizations that improve registration accuracy. These and other advantages will be evident based on the present disclosure.

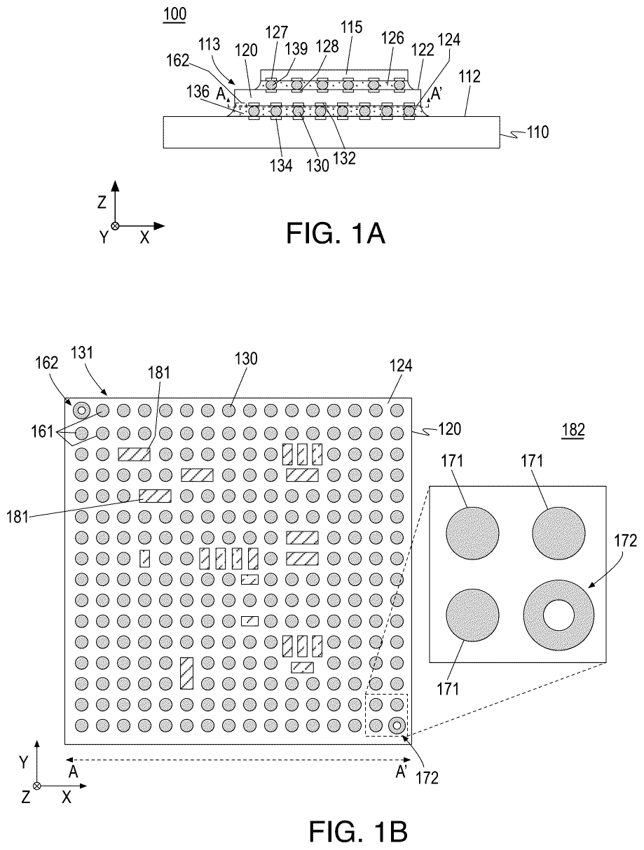

FIG. 1A illustrates a cross-sectional side view of a microelectronic device 100 having a package substrate 120 with an optimized land side fiducial structure 162, arranged in accordance with some embodiments. FIG. 1B illustrates a cross-sectional plan view of a land side 124 of package substrate 120. The cross-sectional plan view of FIG. 1B is taken at A-A′ of FIG. 1A.

As shown in FIG. 1A, microelectronic device 100 includes a microelectronics board 110 or substrate. At least one integrated circuit package 113 is attached to a first surface 112 of microelectronics board 110 by a number of device interconnects 130. Device interconnects 130 may extend between bond pads 132 formed in or on a side 124 of a package substrate 120 and substantially mirror-image bond pads 134 formed in or on first surface 112 of microelectronics board 110. As used herein, device interconnects 130 and/or bond pads 132, which also may be characterized as lands, or other visible metallizations for interconnecting to microelectronics board 110 are characterized as interconnect structures. For example, during processing of package substrate 120, interconnect structures such as device interconnects 130 (e.g., balls), bond pads 132, or the like as well as land side fiducial structure 162 are visible within a field of view. Land side fiducial structure 162 is used for registration of the processing tool while the visible interconnect structures may be disadvantageously mischaracterized as fiducial structures.

With continued reference to FIG. 1A, an integrated circuit device 115 such as a processor, memory, or the like may be attached to a die side 122 of package substrate 120. As shown, integrated circuit device 115 may be attached to die side 122 of package substrate 120 by a number of device interconnects 139 that extend between bond pads 127 formed in or on an active surface of integrated circuit device 115 and bond pads 128 formed in or on die side 122 of package substrate 120. In some embodiments, device interconnects 139 are characterized as first level interconnects (i.e., from die to package) and device interconnects 130 are characterized as second level interconnects (i.e., from package to host). In some embodiments, one or more additional integrated circuit devices are coupled to die side 122 of package substrate 120 and/or one or more additional integrated circuit devices are coupled to a backside of integrated circuit device 115.

Integrated circuit device 115 and/or additional integrated circuit devices may be any appropriate electronic devices, including, but not limited to, a microprocessor, a chipset, a graphics device, a wireless device, a memory device, an application specific integrated circuit device, combinations thereof, stacks thereof, or the like. Although illustrated with a single integrated circuit package, other integrated circuit device structures such multi-device stacks may be used. Device interconnects 130, 139 may be any appropriate electrically conductive material or structure, including but not limited to solder balls, metal bumps or pillars, or metal filled epoxies. For example, device interconnects 130, 139 may be solder balls formed from tin, lead/tin alloys, tin alloys (e.g., tin/bismuth, tin/silver, tin/silver/copper, or tin/copper), copper bumps or pillars, or metal bumps or pillars coated with a solder material. In some embodiments, interconnects 130 are a ball grid array. In some embodiments, interconnects 139 are solder bumps. Underfill material 136, 126 such as an epoxy material, may be disposed between surfaces of package substrate 120 and microelectronics board 110 and between surfaces of integrated circuit device 115 and package substrate 120.

Microelectronics board 110 may include dielectric material layers, which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, as well as laminates or multiple layers thereof, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. For example, microelectronics board 110 may be a motherboard.

Package substrate 120 may be any appropriate package substrate structure, including, but not limited to, a cored package substrate, a coreless package substrate, or an interposer. Package substrate 120 has land side 124 or land side surface and die side 122 or die side surface. In some embodiments, package substrate 120 includes a plurality of dielectric material layers (not shown) that may include build-up films and/or solder resist layers that may be composed of an appropriate dielectric material, including, but not limited to, materials listed with respect to microelectronics board 110.

As shown in FIG. 1B, land side 124 of package substrate 120 includes an array of interconnect structures 131 such as device interconnects 130 that are arrayed in a grid pattern with some of the interconnect structures 131 removed such that discrete devices 181 such as passive components may be positioned within array of interconnect structures 131. In contrast to prior solutions, where such devices are position in dedicated cavities or keep out zones of package substrate 120, interconnect structures 131 are positioned anywhere in array of interconnect structures 131, instead of being restricted to particular regions of land side 124. Such land side device anywhere architectures offer a variety of advantages including design flexibility and reduced spacing while requiring more accurate placement and, in turn, improved registration during pick and place operations. Devices 181 may be any suitable devices such as capacitors, resistors, inductors, diodes, or the like. Furthermore, devices may be located at any positions within array of interconnect structures 131.

Fiducial structures such as fiducial structure 162 and fiducial structure 172 are located on land side 124 to register package substrate 120 during processing. Advantageously, cross-sectional shapes of fiducial structures 162, 172 are different than those of each of array of interconnect structures 131. As discussed, a lateral cross-sectional shape of fiducial structures 162, 172 and each of array of interconnect structures 131 are cross-sectional shapes taken at a plane substantially parallel to land side 124. That is, the cross-sectional shape is taken in the x-y plane and the cross-sectional shape is the shape visible by an imaging device taking an image along an image axis orthogonal to the x-y plane such that the image axis is aligned with the z-dimension.

In particular, the cross-sectional shape of fiducial structure 162 is different with respect to the cross-sectional shapes of interconnect structures 161 that are immediately adjacent to fiducial structure 162. Similarly, the cross-sectional shape of fiducial structure 172 is different with respect to the cross-sectional shapes of interconnect structures 171 that are immediately adjacent to fiducial structure 162. As shown in enlarged view 182, in some embodiments, interconnect structures 171 have a circular cross-sectional shape and fiducial structure 172 has an annular, ring, or donut cross-sectional shape. Although illustrated with respect to annular, ring, or donut cross-sectional shapes, fiducial structures 162, 172 may have any shapes discussed herein such as triangular, H-shape, or I-shape. In addition or in the alternative, fiducial structures 162, 172 may have different sizes with respect to interconnect structures 161, 171.

Furthermore, fiducial structures 162, 172 may have the same size and shape or they may be different in one or both aspects. In some embodiments, fiducial structure 162 is located at a first corner of land side 124 of package substrate 120 and fiducial structure 172 is located at a second diagonal corner of land side 124 of package substrate 120. However, other locations may be used. Although illustrated with two fiducial structures 162, 172, additional fiducial structures 162, 172 may be deployed.

In some embodiments, the bulk or image background of land side 124 of package substrate 120 is a dielectric material such as solder resist or the like. Device interconnects 130 or other exposed structures of array of interconnect structures 131 are another material such as a metal (e.g., solder or copper). Fiducial structures 162, 172 may be the same material as interconnect structures 131 or they may be another material such as a metal that is different than the bulk or image background material of land side 124 of package substrate 120. In some embodiments, land side 124 is a dielectric material such as solder resist and both array of interconnect structures 131 and fiducial structures 162, 172 are an exposed metal such as copper. For example, openings of the dielectric material may expose an underlying copper pad or a copper pad may be formed on the dielectric material. In other embodiments, fiducial structures 162, 172 are an exposed metal such as copper and array of interconnect structures 131 are a balls of solder, for example. Other configurations are available with the commonality being that, while being imaged, fiducial structures 162, 172 may be contrasted with the bulk material of land side 124 while potentially being mistaken for array of interconnect structures 131.

Notably, land side 124 of package substrate 120 includes unit dedicated fiducial structures 162, 172 that are used for registration of package substrate 120 instead of keep out zone level fiducials (i.e., fiducials placed in dedicated keep out zones, which are absent from land side 124). By using fiducial structures 162, 172 having ring shapes, donut shapes, double ring shapes, I-shapes, H-shapes, or triangles, the fiducial markings improve registration, thereby avoiding confusion with neighboring interconnect structures 161, 171. By deploying a dedicated unit fiducial or fiducials (e.g., fiducials for the entirety of package substrate 120) of different shapes, such as ring, donut, or others, and/or different size, recognition of the fiducial(s) is improved and higher location accuracy is achieved. Furthermore, such techniques advantageously avoid confusion while detecting the fiducial(s) relative to neighboring interconnect structures 161, 171 such as pads of the same material, even with reduced spacing. Such fiducial recognition and registration may be deployed in any context such as pick and place of devices 181, inspection of land side 124 of package substrate 120, device test, and so on.

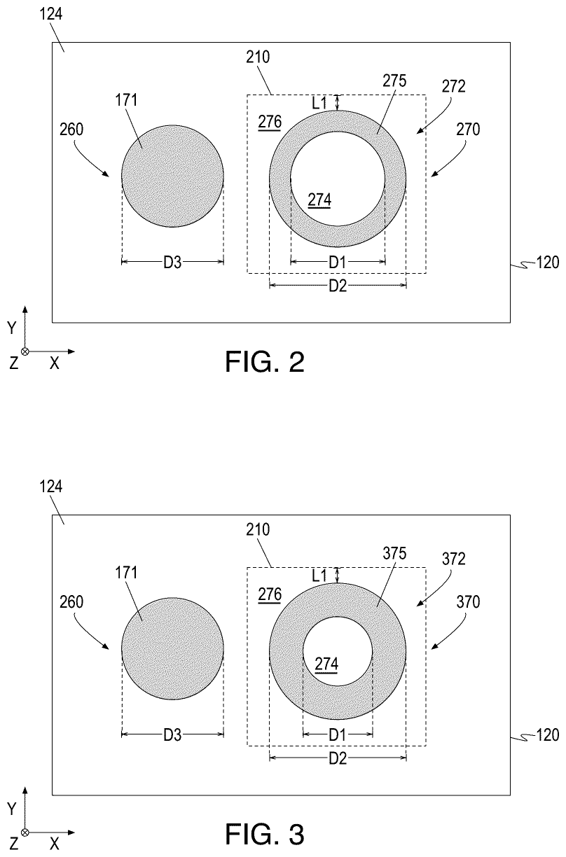

FIG. 2 illustrates a cross-sectional plan view of land side 124 having an exemplary ring shaped fiducial structure 272 adjacent to a circular shaped interconnect structure 171, arranged in accordance with some embodiments. In the context of FIGS. 2-9, an enlarged portion of the view taken at A-A′ of FIG. 1A is illustrated. Furthermore, the fiducial and interconnect structures illustrated in FIGS. 2-9 may be deployed in any context herein such as in package substrate 120, integrated circuit package 113, microelectronic device 100, or any other implementation such as methods 1000, microelectronic device assembly 1200, and so on.

In some embodiments, an apparatus includes a package substrate including a land side and an opposing die side such that the land side is to couple to a microelectronics board and the land side includes a first material such as a dielectric material, an interconnect structure on the land side such that the interconnect structure is a second material such as a metal, and a fiducial structure on the land side and adjacent to the interconnect structure such that the fiducial structure is the second material or a third material (i.e., another metal) and the fiducial structure is adjacent to a corner of the package substrate. The fiducial and interconnect structures may have any shapes, sizes, or characteristics as illustrated and discussed with respect to FIGS. 2-9.

As shown in FIG. 2, fiducial structure 272 may have a ring shape 270 that is different than a circular shape 260 of interconnect structure 171. As used herein, the terms circle, circular shape, or the like indicate a continuous circle shape (i.e., without break). The terms ring shape, annular, annulus shaped, or the like indicate a shape or region between two substantially concentric circles or round shapes. Ring shape 270 includes a segment 275 that is, in this case, an unbroken ring shape or annulus between a region 274 of a first material such as a dielectric (illustrated in white) and an outer region 276 of the first material. For example, segment 275 is between a circular outer shape and a circular inner shape in the context of FIG. 2. In contrast, ring shape 270 of fiducial structure 272 is a different second material such as a metal (illustrated in grey). The first and second materials provide image contrast for detection of fiducial structure 272. Although illustrated with interconnect structure 171 having circular shape 260, other shapes may be used such as square or rectangular so long as interconnect structure 171 and fiducial structure 272 (or other fiducial structures discussed herein) have different shapes.

In addition or in the alternative, fiducial structure 272 and interconnect structure 171 may be different sizes. In the embodiment of FIG. 2, circular shape 260 of interconnect structure 171 has a diameter D3 that may be in the range of about 90 to 100 um. Ring shape 270 of fiducial structure 272 has an outer diameter D2 and an inner diameter D1. In some embodiments, outer diameter D2 is not less than 10% larger than diameter D3. In some embodiments, outer diameter D2 is not less than 25% larger than diameter D3. In some embodiments, outer diameter D2 is not less than 50% larger than diameter D3. In some embodiments, outer diameter D2 is in the range of 10 to 50% larger than diameter D3. In some embodiments, outer diameter D2 is in the range of 130 to 170 um. In some embodiments, outer diameter D2 is about 150 um. In some embodiments, inner diameter D1 is in the range of 90 to 130 um. In some embodiments, inner diameter D1 is about 110 um. In some embodiments, interconnect structure 171 has a first area within a perimeter thereof as defined by circular shape 260 and fiducial structure 272 has a second area within a perimeter thereof as defined by the outer ring of segment 275, and the second area is not less than 25% greater than the first area.

In some embodiments, a void region 210 may be defined around ring shape 270 of fiducial structure 272 such that no other features (e.g., interconnect structure 171) may encroach within void region 210. In some embodiments, void region 210 is defined as a square region around ring shape 270 of fiducial structure 272. In some embodiments, void region 210 is defined by a ring around ring shape 270 of fiducial structure 272. For example, void region 210 may be defined by a keep out distance L1 around ring shape 270. In some embodiments, keep out distance L1 is 25 to 40% of outer diameter D2. In some embodiments, keep out distance L1 is about one-third of outer diameter D2. In some embodiments, keep out distance L1 is in the range of 40 to 60 um. In some embodiments, keep out distance L1 is about 50 um.

FIG. 3 illustrates a cross-sectional plan view of land side 124 having an exemplary thick ring shaped fiducial structure 372 adjacent to circular shaped interconnect structure 171, arranged in accordance with some embodiments. Fiducial structure 372 has a thicker ring shape 370 that is different than circular shape 260 of interconnect structure 171. Ring shape 370 includes a segment 375 that is, in this case, an unbroken ring shape or annulus between a region 374 of a first material such as a dielectric and an outer region 376 of the first material. Segment 375 is between a circular outer shape and a circular inner shape in FIG. 3. Ring shape 370 of fiducial structure 372 is a different second material such as a metal.

Fiducial structure 372 and interconnect structure 171 may also be different sizes. Circular shape 260 of interconnect structure 171 has a diameter D3 as discussed above. In the embodiment of FIG. 3, ring shape 370 of fiducial structure 372 has an outer diameter D2 and an inner diameter D1. In some embodiments, outer diameter D2 is not less than 10% larger than diameter D3. In some embodiments, outer diameter D2 is not less than 25% larger than diameter D3. In some embodiments, outer diameter D2 is not less than 50% larger than diameter D3. In some embodiments, outer diameter D2 is in the range of 10 to 50% larger than diameter D3. In some embodiments, outer diameter D2 is in the range of 120 to 160 um. In some embodiments, outer diameter D2 is about 140 um. In some embodiments, inner diameter D1 is in the range of 60 to 100 um. In some embodiments, inner diameter D1 is about 80 um. In some embodiments, interconnect structure 171 has a first area within a perimeter thereof as defined by circular shape 260 and fiducial structure 372 has a second area within a perimeter thereof as defined by the outer ring of segment 375, and the second area is not less than 25% greater than the first area. Void region 210 may be provided around ring shape 370 of fiducial structure 372 as discussed above.

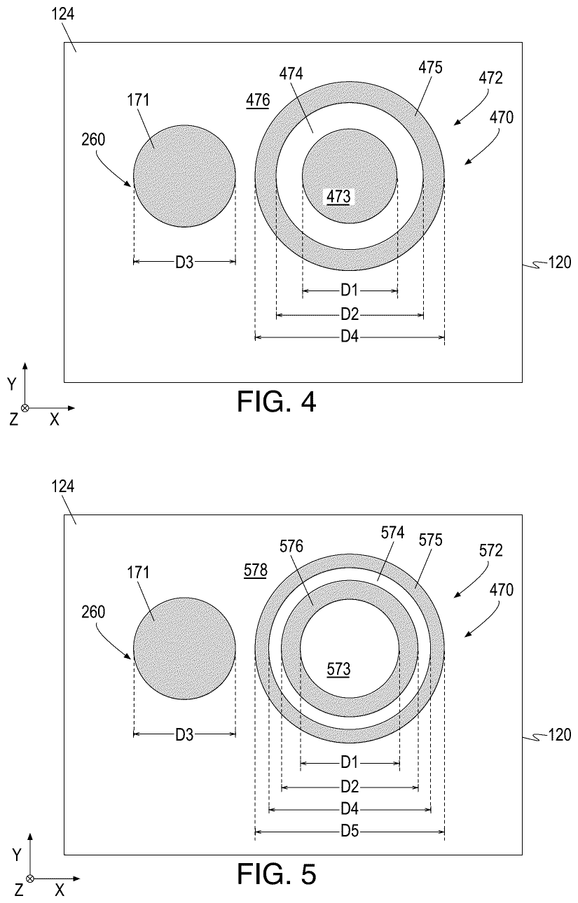

FIG. 4 illustrates a cross-sectional plan view of land side 124 having an exemplary donut shaped fiducial structure 472 adjacent to circular shaped interconnect structure 171, arranged in accordance with some embodiments. As shown in FIG. 4, fiducial structure 472 may have a donut shape 470, which may also be characterized as a circle within an annulus shape or a ring surrounding a circle shape. Donut shape 470 is different than a circular shape 260 of interconnect structure 171. As used herein, the terms donut shape, ring surrounding a circle shape, circle within an annulus shape, or the like indicate a continuous circle shape surrounded by an annulus with a region therebetween. Donut shape 470 includes a segment 475 that is, in this case, an unbroken ring shape or annulus surrounding a region 474 (which also has the shape of an annulus) of a first material such as a dielectric (illustrated in white) and between region 474 and an outer region 476 of the first material. As discussed, donut shape 470 of fiducial structure 472 is a different second material such as a metal (illustrated in grey). Donut shape 470 further includes a circular segment 473 within segment 475 and region 474. For example, circular segment 473 and annular segment 475 may be concentric.

Fiducial structure 472 and interconnect structure 171 may also be different sizes. Circular shape 260 of interconnect structure 171 has diameter D3 as discussed above. Donut shape 470 of fiducial structure 472 includes annular segment 475 and circular segment 473. Annular segment 475 has an outer diameter D4 and an inner diameter D2. In some embodiments, outer diameter D4 is not less than 10% larger than diameter D3. In some embodiments, outer diameter D4 is not less than 25% larger than diameter D3. In some embodiments, outer diameter D4 is not less than 50% larger than diameter D3. In some embodiments, outer diameter D4 is in the range of 10 to 50% larger than diameter D3. In some embodiments, outer diameter D4 is in the range of 130 to 170 um. In some embodiments, outer diameter D4 is about 150 um. In some embodiments, inner diameter D2 is in the range of 90 to 130 um. In some embodiments, inner diameter D2 is about 110 um. Circular segment 473 has diameter D1, which may be in the range of 50 to 90 um, 30 to 70, or about 50 um in various embodiments. In some embodiments, interconnect structure 171 has a first area within a perimeter thereof as defined by circular shape 260 and fiducial structure 472 has a second area within a perimeter thereof as defined by the outer ring of segment 475, and the second area is not less than 25% greater than the first area. In some embodiments, a void region may be defined around annular segment 475 of fiducial structure 472, as discussed with respect to FIGS. 2 and 3.

FIG. 5 illustrates a cross-sectional plan view of land side 124 having an exemplary double ring shaped fiducial structure 572 adjacent to circular shaped interconnect structure 171, arranged in accordance with some embodiments. As shown in FIG. 5, fiducial structure 572 may have a double ring shape 570, double annulus shape, or the like. Double ring shape 570 is different than a circular shape 260 of interconnect structure 171. Double ring shape 570 includes a segment 575 that is, in this case, an unbroken ring shape or annulus surrounding a region 474 (which also has the shape of an annulus), and surrounding a segment 576 that is also an unbroken ring shape or annulus, which surrounds region 573. Regions 573, 574 and an outer region 578 are a first material such as a dielectric material and segments 575, 576 are a second material such as a metal.

Fiducial structure 572 and interconnect structure 171 may also be different sizes. Circular shape 260 of interconnect structure 171 has diameter D3 as discussed above. Double ring shape 570 of fiducial structure 572 includes annular segment 575 and annular segment 576. Annular segment 575 has an outer diameter D5 and an inner diameter D4. In some embodiments, outer diameter D5 is not less than 10% larger than diameter D3. In some embodiments, outer diameter D5 is not less than 25% larger than diameter D3. In some embodiments, outer diameter D5 is not less than 50% larger than diameter D3. In some embodiments, outer diameter D5 is not less than 100% larger than diameter D3. In some embodiments, outer diameter D5 is in the range of 10 to 100% larger than diameter D3.

Annular segment 576 has an outer diameter D2 and an inner diameter D1. In some embodiments, outer diameter D2 is in the range of 130 to 170 um, inner diameter D1 is in the range of 90 to 130 um, outer diameter D5 is in the range of 200 to 240 um, and inner diameter D4 is in the range of 160 to 210 um. In some embodiments, outer diameter D2 is about 150 um, inner diameter D1 is about 110 um, outer diameter D5 is about 215 um, and inner diameter D4 is about 185 um.

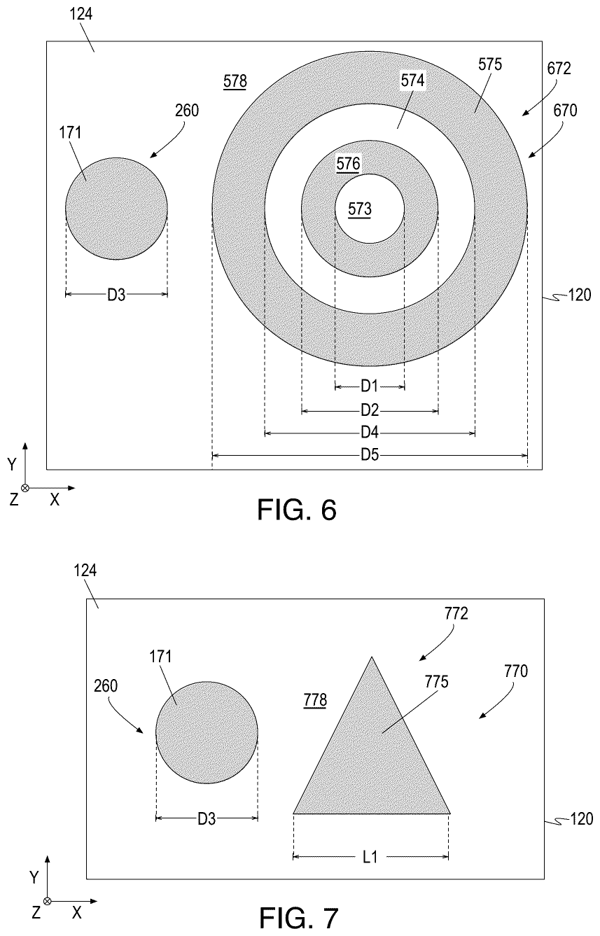

FIG. 6 illustrates a cross-sectional plan view of land side 124 having an exemplary double ring shaped fiducial structure 672 with a thicker rings adjacent to circular shaped interconnect structure 171, arranged in accordance with some embodiments. As shown in FIG. 6, fiducial structure 672 has a double ring shape 670 or double annulus shape. Double ring shape 670 is different than a circular shape 260 of interconnect structure 171. Double ring shape 670 includes segment 575, region 474, segment 576, and region 573 as discussed with respect to FIG. 5. As discussed, regions 573, 574 and outer region 578 are a first material such as a dielectric material and segments 575, 576 are a second material such as a metal.

Fiducial structure 672 and interconnect structure 171 may also be different sizes. Circular shape 260 of interconnect structure 171 has diameter D3 as discussed above. Double ring shape 670 of fiducial structure 572 includes annular segments 575, 576. Annular segment 575 has an outer diameter D5 and an inner diameter D4. In some embodiments, outer diameter D5 is not less than one and a half times larger than diameter D3. In some embodiments, outer diameter D5 is not less than two times larger than diameter D3. In some embodiments, outer diameter D5 is not less than three times larger than diameter D3. In some embodiments, outer diameter D5 is in the range of one and a half to three times larger than diameter D3.

In some embodiments, outer diameter D2 is in the range of 130 to 170 um, inner diameter D1 is in the range of 90 to 130 um, outer diameter D5 is in the range of 340 to 390 um, and inner diameter D4 is in the range of 190 to 230 um. In some embodiments, outer diameter D2 is about 150 um, inner diameter D1 is about 110 um, outer diameter D5 is about 365 um, and inner diameter D4 is about 210 um. In some embodiments, a void region may be defined around annular segment 575 of fiducial structure 572, as discussed with respect to FIGS. 2 and 3.

FIGS. 5 and 6 illustrate exemplary double ring fiducial shapes and sizes. Other sizes are available. With reference to FIG. 6, in some embodiments, outer diameter D2 is in the range of 120 to 160 um, inner diameter D1 is in the range of 60 to 100 um, outer diameter D5 is in the range of 180 to 230 um, and inner diameter D4 is in the range of 160 to 210 um. In some embodiments, outer diameter D2 is about 140 um, inner diameter D1 is about 80 um, outer diameter D5 is about 205 um, and inner diameter D4 is about 175 um. In some embodiments, outer diameter D2 is in the range of 120 to 160 um, inner diameter D1 is in the range of 60 to 100 um, outer diameter D5 is in the range of 330 to 380 um, and inner diameter D4 is in the range of 190 to 230 um. In some embodiments, outer diameter D2 is about 140 um, inner diameter D1 is about 80 um, outer diameter D5 is about 355 um, and inner diameter D4 is about 210 um. Other dimensions may be used. In some embodiments, interconnect structure 171 has a first area within a perimeter thereof as defined by circular shape 260 and fiducial structure 572, 672 has a second area within a perimeter thereof as defined by the outer ring of segment 575, and the second area is not less than 25% greater than the first area.

FIG. 7 illustrates a cross-sectional plan view of land side 124 having an exemplary triangular shaped fiducial structure 772 adjacent to circular shaped interconnect structure 171, arranged in accordance with some embodiments. As discussed, interconnect structure 171 may have any shape such as circular, square, or rectangular such that it is different than adjacent fiducial structure 772. As shown in FIG. 7, fiducial structure 772 may have a triangular shape 770 that is different than circular shape 260 of interconnect structure 171. As used herein, the term triangle, triangle shape, or triangular shape, or the like indicate a continuous triangle shape (i.e., without break). Although illustrate with a continuous triangle shape segments of such shapes similar to the discussed annular embodiments may be deployed. Triangular shape 770 includes a region 775 that is a first material such as metal that is within a field or region of a second material such as dielectric of outer region 778 of land side 124 of package substrate 120. Although illustrated with an equilateral triangular shape, other triangular shapes may be used such as right triangles.

In addition or in the alternative, fiducial structure 772 and interconnect structure 171 may be different sizes. For example, triangular shape 770 of fiducial structure 772 may have an edge length L1 that is greater than diameter D3 of circular shape 260 of interconnect structure 171. As discussed, diameter D3 of circular shape 260 may be in the range of about 90 to 100 um. In some embodiments, edge length L1 is not less than 10% larger than diameter D3, not less than 25% larger than diameter D3, not less than 50% larger than diameter D3, or in the range of 10 to 50% larger than diameter D3. In some embodiments, edge length L1 is in the range of 130 to 170 um. In some embodiments, edge length L1 is about 150 um. In some embodiments, edge length L1 is in the range of 180 to 220 um. In some embodiments, edge length L1 is about 200 um. Other edge lengths may be used. In some embodiments, interconnect structure 171 has a first area within a perimeter thereof as defined by circular shape 260 and fiducial structure 772 has a second area within a perimeter thereof as defined by triangular shape 770, and the second area is not less than 25% greater than the first area. In some embodiments, a void region may be defined, as discussed above.

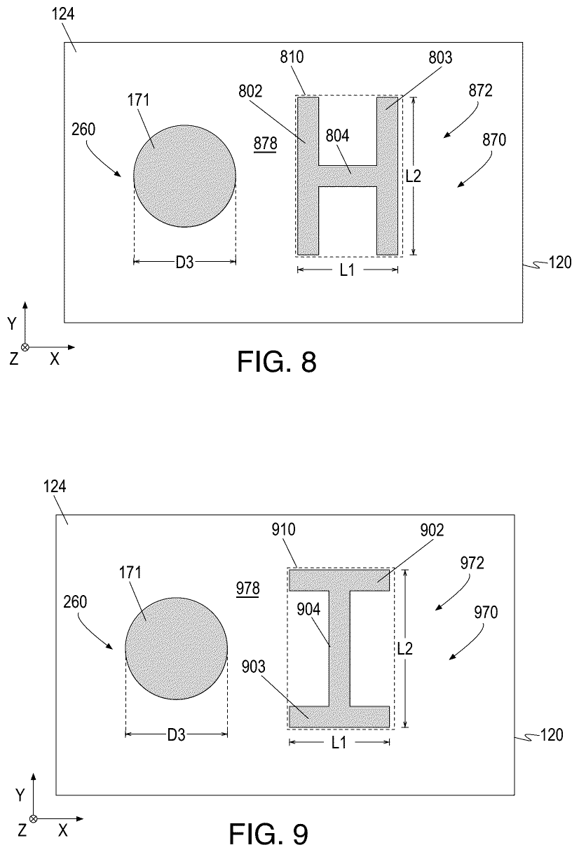

FIG. 8 illustrates a cross-sectional plan view of land side 124 having an exemplary H-shaped fiducial structure 872 adjacent to circular shaped interconnect structure 171, arranged in accordance with some embodiments. As discussed, interconnect structure 171 may have any shape such as circular, square, or rectangular such that it is different than adjacent fiducial structure 872. As shown in FIG. 8, fiducial structure 872 may have an H-shape 870 that is different than circular shape 260 of interconnect structure 171. As used herein, the term H-shape,

H-shaped, or the like indicates a shape having multiple segments that provide an H-shape such that two segments are substantially parallel and a third segment connects the first two segments by extending between them. In some embodiments, the third segment bisects the first two segments. H-shape 870 includes a first segment 802 extending in the y-direction, a second segment 803 substantially parallel to the first segment and also extending in the y-direction, and a third segment 804 that extends in the x-direction and couples to both first segment 802 and second segment 803. In the example of FIG. 8, third segment 804 bisects first segment 802 and second segment 803, however third segment 804 may intersect at a point other than the centerpoints of first segment 802 and second segment 803. Furthermore, in some embodiments, third segment 804 may extend at an angle less than about 10° relative to the x-direction. As discussed, segments 802, 803, 804 are a first material such as metal that is within a field or region of a second material such as dielectric of region 878 of land side 124 of package substrate 120.

In addition or in the alternative, fiducial structure 872 and interconnect structure 171 may be different sizes. For example, H-shape 870 of fiducial structure 872 may have orthogonal edge lengths L1, L2 that are greater than diameter D3 of circular shape 260 of interconnect structure 171. As discussed, diameter D3 of circular shape 260 may be in the range of about 90 to 100 um. In some embodiments, one or both of edge lengths L1, L2 are not less than 10% larger than diameter D3, not less than 25% larger than diameter D3, not less than 50% larger than diameter D3, or in the range of 10 to 50% larger than diameter D3. In some embodiments, one or both of edge lengths L1, L2 are in the range of 130 to 170 um. In some embodiments, one or both of edge lengths L1, L2 are about 150 um. In some embodiments, one or both of edge lengths L1, L2 are in the range of 180 to 220 um. In some embodiments, one or both of edge lengths L1, L2 are about 200 um. Other edge lengths may be used. In some embodiments, interconnect structure 171 has a first area within a perimeter thereof as defined by circular shape 260 and fiducial structure 872 has a second area within a perimeter 810 thereof as defined by the outermost points of segments 802, 803, and the second area is not less than 25% greater than the first area. In some embodiments, a void region may be defined, as discussed above.

FIG. 9 illustrates a cross-sectional plan view of land side 124 having an exemplary I-shaped fiducial structure 972 adjacent to circular shaped interconnect structure 171, arranged in accordance with some embodiments. Interconnect structure 171 may have any shape such as circular, square, or rectangular such that it is different than adjacent fiducial structure 972. As shown in FIG. 9, fiducial structure 972 may have an I-shape 970 that is different than circular shape 260 of interconnect structure 171. As used herein, the term I-shape, I-shaped, or the like indicates a shape, similar to an H-shape but having different orientation and/or aspect ratio, having multiple segments that provide an I-shape such that two segments are substantially parallel and a third segment connects the first two segments by extending between them. In some embodiments, the third segment bisects the first two segments. I-shape 970 includes a first segment 902 extending in the x-direction, a second segment 903 substantially parallel to the first segment and also extending in the x-direction, and a third segment 904 that extends in the y-direction and couples to both first segment 902 and second segment 903. For example, third segment 904 may bisect first segment 902 and second segment 903 or third segment 904 may intersect at a point other than the centerpoints of first segment 902 and second segment 903. In various embodiments, third segment 904 may extends orthogonal to first segment 902 and second segment 903 (i.e., in the y-direction) or third segment 902 may extend at an angle of less that about 10° relative to the y-direction. Segments 902, 903, 904 are a first material such as metal that is within a field or region of a second material such as dielectric of region 978 of land side 124 of package substrate 120.

Fiducial structure 972 and interconnect structure 171 may also be different sizes. For example, I-shape 970 of fiducial structure 972 may have orthogonal edge lengths L1, L2 that are greater than diameter D3 of circular shape 260 of interconnect structure 171. For example, diameter D3 and edge lengths L1, L2 may have any characteristics discussed with respect to FIG. 8 above. In some embodiments, interconnect structure 171 has a first area within a perimeter thereof as defined by circular shape 260 and fiducial structure 972 has a second area within a perimeter 910 thereof as defined by the outermost points of segments 902, 903, and the second area is not less than 25% greater than the first area. In some embodiments, a void region may be defined, as discussed above.

Such fiducial structure shapes offer improved detection and accuracy in package substrate registration during processing such as pick and place operations, inspection, and the like. Such fiducial structure shapes may be ring shape, double ring shape, donut shape, H-shape, I-shape, or the like for improved processing accuracy.

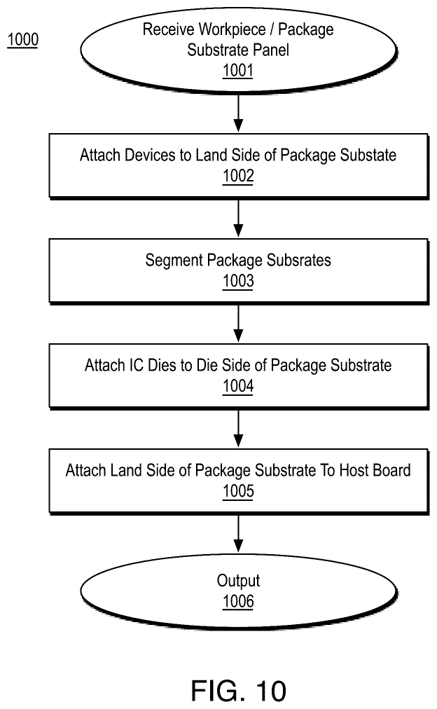

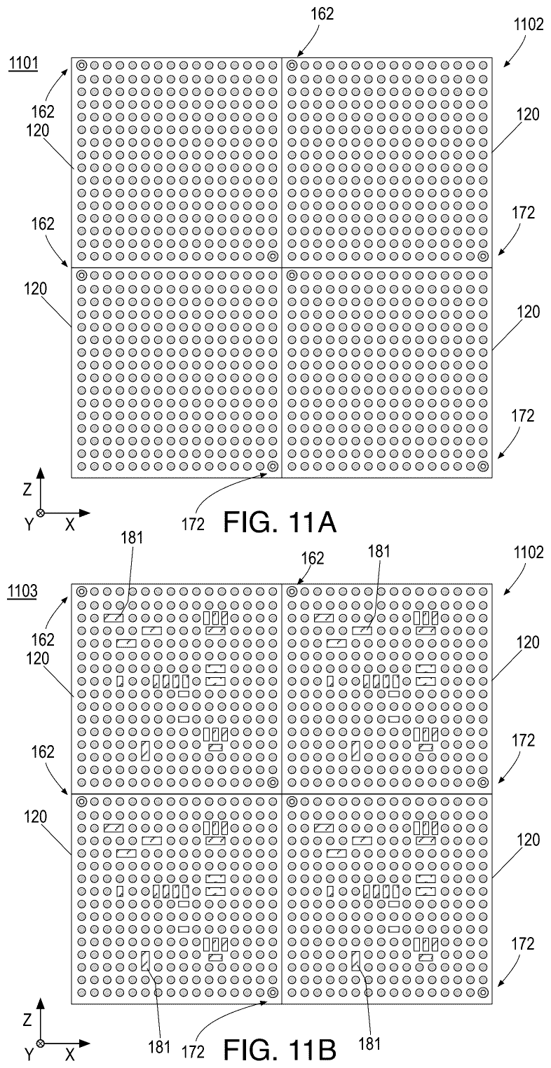

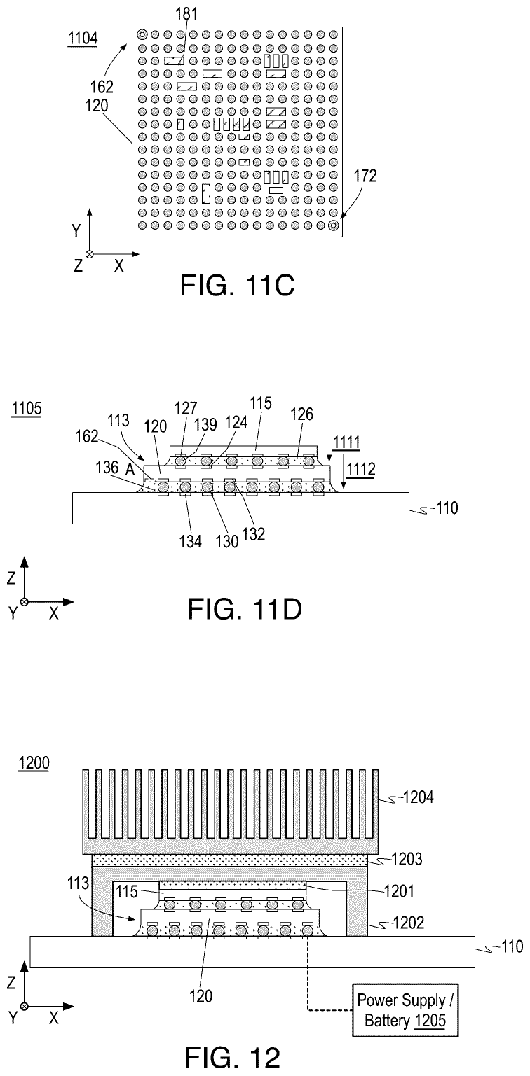

FIG. 10 is a flow diagram illustrating example methods 1000 for forming a microelectronic device including an optimized land side fiducial structure, arranged in accordance with some embodiments. FIGS. 11A, 11B, 11C, and 11D illustrate cross-sectional side views of device structures as the operations of methods 1000 are performed, arranged in accordance with some embodiments. As shown, methods 1000 begins at operation 1001, where a workpiece such as a package substrate panel is received for processing. The package substrate panel may be any suitable substrate as discussed herein and may have any number of discrete package substrate units such as four to 70, or more. The package substrate panel may be preprocessed to form an array of interconnect structures, as well as fiducial structures having any shapes and sizes discussed herein.

FIG. 11A illustrates an example device structure 1101. As shown, device structure 1101 includes a package substrate panel 1102 including a number of package substrate units or package substrates 120 prior to segmentation. As shown, each of package substrates 120 include optimized land side fiducial structures 162, 172 at diagonal corners thereof. As used herein, the term adjacent to a corner indicates a structure is near a corner. The term at a corner indicates no other similar structure is between the structure and the corner. In the illustrated embodiment, each of land side fiducial structures 162, 172 are at the corners of package substrates 120. However, on or more similar structures may be between land side fiducial structures 162, 172 and the corners of package substrates 120 in some embodiments. Notably, package substrate panel 1102 may undergo any suitable processing where land side fiducial structures 162, 172 are used for registration of package substrates 120 on the tool, as is known in the art. In the examples discussed herein, the processing includes pick and place operations. However, registration using land side fiducial structures 162, 172 may be performed in any suitable processing context such as inspection, test, lithography, or others.

Returning to FIG. 10, processing continues at operation 1002, where devices such as passive devices are attached to the land side of the package substrate. Such devices may be any suitable electronics devices such as capacitors, resistors, inductors, diodes, or the like, heat removal devices such as metal shunts, or others. In some embodiments, a package substrate is received (as a part of a package substrate panel or stand-alone) that includes a land side having a dielectric material, an array of metal interconnect structures, and a metal fiducial structure having any of the characteristics discussed above. At operation 1002, the package substrate is registered using the fiducial structure and the registration is used to attach the devices to the land side of the package substrate. Such device attachment may be performed by a pick and place tool for example

FIG. 11B illustrates an example device structure 1103 similar to device structure 1101 after attaching devices 181 to the land side of package substrate 113 of package substrate panel 1102. In some embodiments, devices 181 (or components) are placed on the land side of package substrates 120 based on registration using fiducial structures 162, 172 as discussed above. Fiducial structures 162, 172 may have any shapes and other characteristics discussed herein. The placed components may be electronic devices, heat removal devices, or others.

Returning to FIG. 10, processing continues at operation 1003, where the package substrate panel may be segmented to provide a plurality of package substrate units for continued processing. The package substrate units may be segmented from the package substrate panel using any suitable technique or techniques such as sawing, laser ablation, and the like.

FIG. 11C illustrates an example device structure 1104 similar to device structure 1103 after segmentation of package substrate 113 from package substrate panel 1102. Although illustrated with segmentation of package substrate 113 prior to continued processing, in some embodiments die attach or other operation may be performed on package substrate panel 1102 prior to segmentation.

Returning to FIG. 10, processing continues at operation 1004, where integrated circuit dies are attached to the die side (i.e., opposite the land side) of the package substrate. Such integrated circuit die attach may be performed using any suitable technique or techniques such as solder ball attach, hybrid bonding techniques, or the like. Processing continues at operation 1005, where the land side of the package substrate is attached to a host board such as mother board. Such package substrate attach may be performed using any suitable technique or techniques such ball grid array coupling, land grid array coupling, or the like.

FIG. 11D illustrates an example device structure 1105 after integrated circuit die attach operation 1111 couples integrated circuit device 115 (e.g., an IC die such as a processor) to package substrate and after package substrate operation 1112 couples integrated circuit package 113 to microelectronics board 110. FIG. 11D thereby matches FIG. 1A discussed above and may include any corresponding characteristics discussed herein.

Returning to FIG. 10, processing continues at operation 1006, where the microelectronics board, integrated circuit device(s), package substrate, etc. is output for continued assembly and incorporation into an electronic device. Such output may be performed at any operation of methods 1000 such as after package substrate segmentation (operation 1003), after IC die attach (operation 1004), mounting of package to host board (operation 1005).

FIG. 12 illustrates an example microelectronic device assembly 1200 including an optimized land side fiducial structure, in accordance with some embodiments. As shown, microelectronic device assembly 1200 includes integrated circuit device 115 attached to package substrate 120 (both as part of integrated circuit package 113), which is in turn attached to microelectronics board 110. In the context of FIG. 12, microelectronic device assembly 1200 includes an optimized land side fiducial structure, as discussed herein. Microelectronic device assembly 1200 may include a power supply and/or battery 1205 coupled to integrated circuit package 113 and/or other components of microelectronic device assembly 1200. The power supply may include a battery, voltage converter, power supply circuitry, or the like.

Microelectronic device assembly 1200 further includes a thermal interface material (TIM) 1201 disposed on a top surface of integrated circuit device 115. TIM 1201 may include any suitable thermal interface material and may be characterized as TIM 1. Integrated heat spreader 1202 having a surface on TIM 1201 extends over integrated circuit device 115, and is mounted to microelectronics board 110. Microelectronics board 110 may include any suitable substrate such as a motherboard, interposer, or the like. Microelectronic device assembly 1200 further includes TIM 1203 disposed on a top surface of integrated heat spreader 1202. TIM 1203 may include any suitable thermal interface material and may be characterized as TIM 2. TIM 1201 and TIM 1203 may be the same material(s) or they may be different. Heat sink 1204 (e.g., an exemplary beat dissipation device or thermal solution) is on TIM 1203 and dissipates heat generated by integrated circuit device 115. Although illustrated with respect to microelectronic device assembly 1200, the various optimized land side fiducial structures discussed herein may be deployed in any suitable architecture and form factor. For example, microelectronic device assembly 1200 may be used in desktop and server form factors. In other contexts, a heat solution such as a heat pipe or heat spreader may be mounted directly on TIM 1201. Such assemblies may be used in smaller form factor devices. Other heat dissipation devices may be used in concert with the heat removal enhancement structures discussed herein. As used herein, the term heat exchanger indicates a structure or device inclusive of any such heat removal solutions inclusive of integrated heat spreaders, heat sinks, heat pipes, and so on.

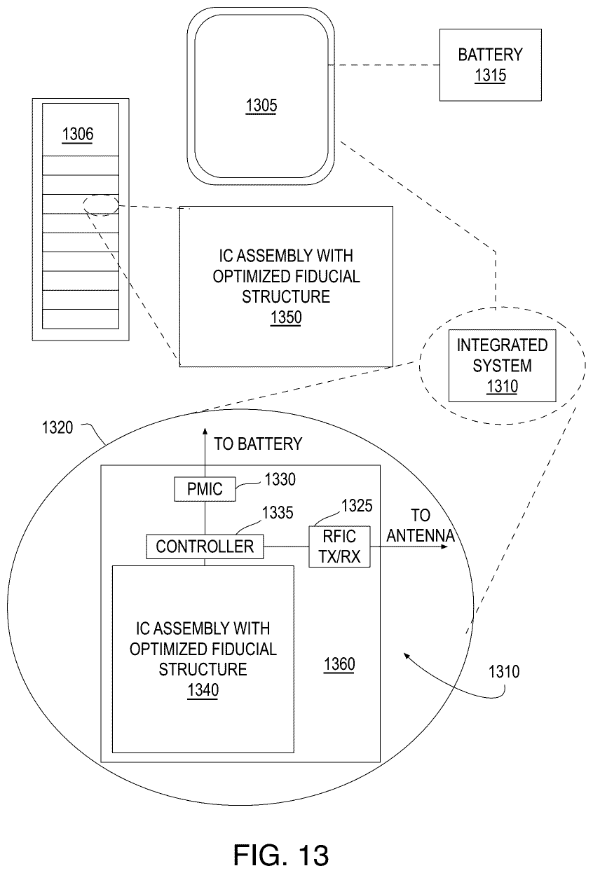

FIG. 13 illustrates exemplary systems employing an optimized land side fiducial structure, in accordance with some embodiments. The system may be a mobile computing platform 1305 and/or a data server machine 1306, for example. Either may employ an optimized land side fiducial structure as described elsewhere herein. Server machine 1306 may be any commercial server, for example including any number of high-performance computing platforms disposed within a rack and networked together for electronic data processing, which in the exemplary embodiment includes an IC die assembly 1350 with an optimized land side fiducial structure as described elsewhere herein. Mobile computing platform 1305 may be any portable device configured for each of electronic data display, electronic data processing, wireless electronic data transmission, or the like. For example, mobile computing platform 1305 may be any of a tablet, a laptop computer, etc., and may include a display screen (e.g., a capacitive, inductive, resistive, or optical touchscreen), a chip-level or package-level integrated system 1310, and a battery 1315. Although illustrated with respect to mobile computing platform 1305, in other examples, chip-level or package-level integrated system 1310 and a battery 1315 may be implemented in a desktop computing platform, an automotive computing platform, an internet of things platform, or the like. As discussed below, in some examples, the disclosed systems may include a sub-system 1360 such as a system on a chip (SOC) or an integrated system of multiple ICs, which is illustrated with respect to mobile computing platform 1305.

Whether disposed within integrated system 1310 illustrated in expanded view 1320 or as a stand-alone packaged device within data server machine 1306, sub-system 1360 may include memory circuitry and/or processor circuitry 1340 (e.g., RAM, a microprocessor, a multi-core microprocessor, graphics processor, etc.), a power management integrated circuit (PMIC) 1330, a controller 1335, and a radio frequency integrated circuit (RFIC) 1325 (e.g., including a wideband RF transmitter and/or receiver (TX/RX)). As shown, one or more IC dice, such as memory circuitry and/or processor circuitry 1340 may be assembled and implemented such that one or more are incorporated in a system having an optimized land side fiducial structure as described herein. In some embodiments, RFIC 1325 includes a digital baseband and an analog front end module further comprising a power amplifier on a transmit path and a low noise amplifier on a receive path). Functionally, PMIC 1330 may perform battery power regulation, DC-to-DC conversion, etc., and so has an input coupled to battery 1315, and an output providing a current supply to other functional modules. As further illustrated in FIG. 13, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1340 may provide memory functionality for sub-system 1360, high level control, data processing and the like for sub-system 1360. In alternative implementations, each of the SOC modules may be integrated onto separate ICs coupled to a package substrate, interposer, or board.

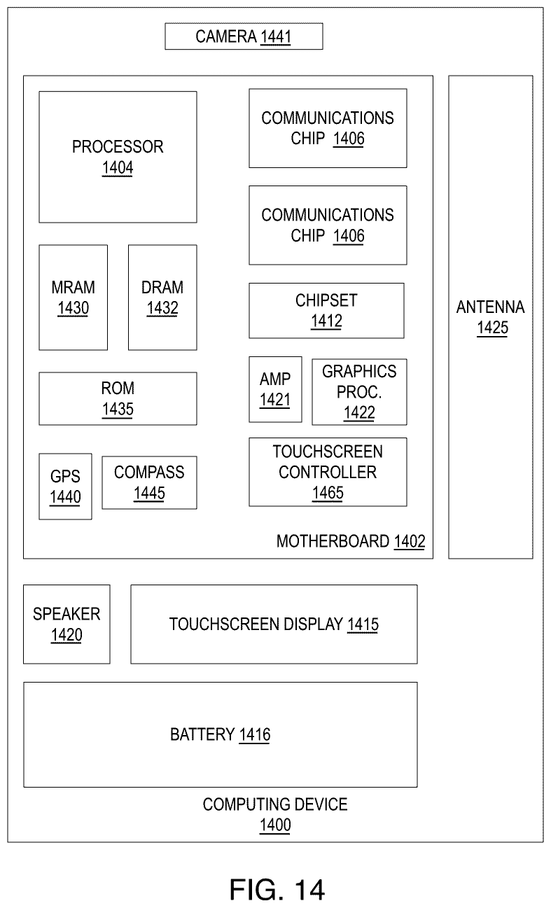

FIG. 14 is a functional block diagram of an electronic computing device 1400, in accordance with some embodiments. For example, device 1400 may, via any suitable component therein, employ an optimized land side fiducial structure in accordance with any embodiments described elsewhere herein. Device 1400 further includes a motherboard or package substrate 1402 hosting a number of components, such as, but not limited to, a processor 1404 (e.g., an applications processor). Processor 1404 may be physically and/or electrically coupled to package substrate 1402. In general, the term “processor” or “microprocessor” may refer to any device or portion of a device that processes electronic data from registers and/or memory to transform that electronic data into other electronic data that may be further stored in registers and/or memory.

In various examples, one or more communication chips 1406 may also be physically and/or electrically coupled to the motherboard 1402. In further implementations, communication chips 1406 may be part of processor 1404. Depending on its applications, computing device 1400 may include other components that may or may not be physically and electrically coupled to motherboard 1402. These other components include, but are not limited to, volatile memory (e.g., DRAM 1432), non-volatile memory (e.g., ROM 1435), flash memory (e.g., NAND or NOR), magnetic memory (MRAM 1430), a graphics processor 1422, a digital signal processor, a crypto processor, a chipset 1412, an antenna 1425, touchscreen display 1415, touchscreen controller 1465, battery 1416, audio codec, video codec, power amplifier 1421, global positioning system (GPS) device 1440, compass 1445, accelerometer, gyroscope, speaker 1420, camera 1441, and mass storage device (such as hard disk drive, solid-state drive (SSD), compact disk (CD), digital versatile disk (DVD), and so forth, or the like.

Communication chips 1406 may enable wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1406 may implement any of a number of wireless standards or protocols, including, but not limited to, those described elsewhere herein. As discussed, computing device 1400 may include a plurality of communication chips 1406. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a package substrate comprising a land side and an opposing die side, the land side to couple to a microelectronics board and the land side comprising a first material, an interconnect structure on the land side, the interconnect structure comprising a second material, and a fiducial structure on the land side and adjacent to the interconnect structure, the fiducial structure comprising the second material or a third material, such that the fiducial structure is adjacent to a corner of the package substrate, the interconnect structure comprises a first lateral cross-sectional shape along or over the land side, the fiducial structure comprises a second lateral cross-sectional shape along or over the land side, the first shape and the second shape are different, and the second shape comprises a triangle or a segment of the second or third material separating regions of the first material.

In one or more second embodiments, further to the first embodiments, the second shape comprises the segment, the segment between an outer shape and an inner shape of the first material.

In one or more third embodiments, further to the first or second embodiments, the segment comprises an annulus.

In one or more fourth embodiments, further to the first through third embodiments, the second shape further comprises a second segment within the segment, the second shape comprising one of an annulus or a circle.

In one or more fifth embodiments, further to the first through fourth embodiments, the second shape comprises the segment and a second segment extending orthogonally from the segment.

In one or more sixth embodiments, further to the first through fifth embodiments, the second segment extends orthogonally from a midpoint of the segment.

In one or more seventh embodiments, further to the first through sixth embodiments, the fiducial structure comprises one of a ring shape, a donut shape, an H-shape or an I-shape.

In one or more eighth embodiments, further to the first through seventh embodiments, the interconnect structure comprises a first area within a first perimeter thereof and the fiducial structure comprises a second area within a second perimeter thereof, and wherein the second area is not less than 25% greater than the first area.

In one or more ninth embodiments, further to the first through eighth embodiments, the apparatus further comprises a second fiducial structure on the land side and adjacent to a second corner of the package substrate, the second corner diagonal from the corner, the second fiducial structure comprising a third lateral cross-sectional shape along or over the land side, such that the third shape and the first shape are different.

In one or more tenth embodiments, further to the first through ninth embodiments, the second shape and the third shape are the same.

In one or more eleventh embodiments, further to the first through tenth embodiments, the apparatus further comprises an array of interconnect structures comprising the interconnect structure, such that the interconnect structure is proximal to the corner relative to each of the remaining interconnect structures of the array of interconnect structures, and such that the array of interconnect structures comprise a land grid array or a ball grid array.

In one or more twelfth embodiments, further to the first through eleventh embodiments, the fiducial structure comprises the second material, the first material comprises a package substrate dielectric and the second material comprises a metal.

In one or more thirteenth embodiments, a system comprises an IC die and/or a microelectronics board attached to the package substrate of any of the first through twelfth embodiments.

In one or more fourteenth embodiments, a system comprises an integrated circuit IC device attached to a first side of a package substrate, a microelectronics board, wherein a second side of the package substrate, opposite the first side, is attached to the microelectronics board, an interconnect structure on the second side of the package substrate, the interconnect structure comprising a first metal, and a fiducial structure on the second side of the package substrate, the fiducial structure comprising the first metal or a second metal, such that the fiducial structure is adjacent to a corner of the package substrate, the interconnect structure comprises a first lateral cross-sectional shape along or over the land side, the fiducial structure comprises a second lateral cross-sectional shape along or over the land side, the first shape and the second shape are different, and the second shape comprises a triangle or a segment of the first or second metal separating regions of a dielectric material.

In one or more fifteenth embodiments, further to the fourteenth embodiments, the second shape comprises the segment and the segment comprises an annulus.

In one or more sixteenth embodiments, further to the fourteenth or fifteenth embodiments, the second shape further comprises a second segment within the segment, the second shape comprising one of an annulus or a circle.

In one or more seventeenth embodiments, further to the fourteenth through sixteenth embodiments, the second shape comprises the segment and a second segment extending orthogonally from the segment.

In one or more eighteenth embodiments, a method comprises receiving a package substrate comprising a land side comprising a dielectric material, the land side comprising an array of metal interconnect structures and a metal fiducial structure proximal to a corner of the package substrate, such that a first of the metal interconnect structures proximal to the metal fiducial structure comprises a first lateral cross-sectional shape along or over the land side, the metal fiducial structure comprises a second lateral cross-sectional shape along or over the land side, the first shape and the second shape are different, and the second shape comprises a triangle or a segment thereof separating regions of the dielectric material, registering the package substrate using the fiducial structure, and placing a component on the land side of the package substrate based on the registration using the fiducial structure.

In one or more nineteenth embodiments, further to the eighteenth embodiments, the second shape comprises the segment and the segment comprises an annulus.

in In one or more twentieth embodiments, further to the eighteenth or nineteenth embodiments, the second shape further comprises a second segment within the segment, the second shape comprising one of an annulus or a circle.

In one or more twenty-first embodiments, further to the eighteenth through twentieth embodiments, the method further comprises segmenting the package substrate from a panel comprising the package substrate, attaching an integrated circuit IC device to a die side of the package substrate opposite the land side, and attaching the land side to a microelectronics board.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a package substrate comprising a land side and an opposing die side, the land side to couple to a microelectronics board and the land side comprising a first material;
an interconnect structure on the land side, the interconnect structure comprising a second material; and
a fiducial structure on the land side and adjacent to the interconnect structure, the fiducial structure comprising the second material or a third material, wherein the fiducial structure is adjacent to a corner of the package substrate, the interconnect structure comprises a first lateral cross-sectional shape along or over the land side, the fiducial structure comprises a second lateral cross-sectional shape along or over the land side, the first shape and the second shape are different, and the second shape comprises a triangle or a segment of the second or third material separating regions of the first material.

2. The apparatus of claim 1, wherein the second shape comprises the segment, the segment between an outer shape and an inner shape of the first material.

3. The apparatus of claim 2, wherein the segment comprises an annulus.

4. The apparatus of claim 3, wherein the second shape further comprises a second segment within the segment, the second shape comprising one of an annulus or a circle.

5. The apparatus of claim 1, wherein the second shape comprises the segment and a second segment extending orthogonally from the segment.

6. The apparatus of claim 5, wherein the second segment extends orthogonally from a midpoint of the segment.

7. The apparatus of claim 1, wherein the fiducial structure comprises one of a ring shape, a donut shape, an H-shape or an I-shape.

8. The apparatus of claim 1, wherein the interconnect structure comprises a first area within a first perimeter thereof and the fiducial structure comprises a second area within a second perimeter thereof, and wherein the second area is not less than 25% greater than the first area.

9. The apparatus of claim 1, further comprising a second fiducial structure on the land side and adjacent to a second corner of the package substrate, the second corner diagonal from the corner, the second fiducial structure comprising a third lateral cross-sectional shape along or over the land side, wherein the third shape and the first shape are different.

10. The apparatus of claim 1, wherein the second shape and the third shape are the same.

11. The apparatus of claim 1, further comprising an array of interconnect structures comprising the interconnect structure, wherein the interconnect structure is proximal to the corner relative to each of the remaining interconnect structures of the array of interconnect structures, and wherein the array of interconnect structures comprise a land grid array or a ball grid array.

12. The apparatus of claim 1, wherein the fiducial structure comprises the second material, the first material comprises a package substrate dielectric and the second material comprises a metal.

13. A system, comprising:
an integrated circuit IC device attached to a first side of a package substrate;
a microelectronics board, wherein a second side of the package substrate, opposite the first side, is attached to the microelectronics board;
an interconnect structure on the second side of the package substrate, the interconnect structure comprising a first metal; and
a fiducial structure on the second side of the package substrate, the fiducial structure comprising the first metal or a second metal, wherein the fiducial structure is adjacent to a corner of the package substrate, the interconnect structure comprises a first lateral cross-sectional shape along or over the second side, the fiducial structure comprises a second lateral cross-sectional shape along or over the second side, the first shape and the second shape are different, and the second shape comprises a triangle or a segment of the first or second metal separating regions of a dielectric material.

14. The system of claim 13, wherein the second shape comprises the segment and the segment comprises an annulus.

15. The system of claim 14, wherein the second shape further comprises a second segment within the segment, the second shape comprising one of an annulus or a circle.

16. The system of claim 13, wherein the second shape comprises the segment and a second segment extending orthogonally from the segment.

17. A method, comprising:
receiving a package substrate comprising a land side comprising a dielectric material, the land side comprising an array of metal interconnect structures and a metal fiducial structure proximal to a corner of the package substrate, wherein a first of the metal interconnect structures proximal to the metal fiducial structure comprises a first lateral cross-sectional shape along or over the land side, the metal fiducial structure comprises a second lateral cross-sectional shape along or over the land side, the first shape and the second shape are different, and the second shape comprises a triangle or a segment thereof separating regions of the dielectric material;
registering the package substrate using the fiducial structure; and
placing a component on the land side of the package substrate based on the registration using the fiducial structure.

18. The method of claim 17, wherein the second shape comprises the segment and the segment comprises an annulus.

19. The method of claim 17, wherein the second shape further comprises a second segment within the segment, the second shape comprising one of an annulus or a circle.

20. The method of claim 17, further comprising:
segmenting the package substrate from a panel comprising the package substrate;
attaching an integrated circuit IC device to a die side of the package substrate opposite the land side; and
attaching the land side to a microelectronics board.
